(19) United States
(12) Patent Application Publication
(10) Pub. No.: US 2016/0209892 A1
(43) Pub. Date: Jul. 21, 2016

(54) HEAT DISSIPATING DEVICE AND HEAT DISSPATING SYSTEM

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: BO YANG, Wuhan (CN); XU LI, Wuhan (CN)

(21) Appl. No.: 14/607,293

(22) Filed: Jan. 28, 2015

(30) Foreign Application Priority Data
Jan. 15, 2015 (CN) 201510019779.6

(51) Int. Cl. G06F 1/20; H05K 7/20

(52) U.S. Cl. CPC G06F 1/20; H05K 7/2039; H05K 7/20272; H05K 7/20136

(57) ABSTRACT

Heat dissipating device includes a storage tank for storing cooling liquid, a driving device located in the storage tank, a heat sink configured to be located above an electronic component, and a cooling tube circulating throughout the heat sink. The storage tank includes an outlet and an intake. A first end of the cooling tube is coupled to the outlet, and a second opposite end of the cooling tube is coupled to the intake. The driving device is used to move the cooling liquid out of the storage tank via the outlet to flow through the cooling pipe, and flow back to the storage tank via the intake for dissipating heat generated by the electronic component. The disclosure further provides a heat dissipating system.

### FIELD

The subject matter herein generally relates to a heat dissipating device and a heat dissipating system with the heat dissipating device.

### BACKGROUND

Heat dissipating devices perform the critical function of dissipating heat from a computer system. For example, a heat sink and a fan are provided to efficiently dissipate heat generated by a Central Processing Unit (CPU). Air is directed out of the computer system by the heat sink and the fan to dissipate heat.

### BRIEF DESCRIPTION OF THE DRAWINGS

Implementations of the present technology will now be described, by way of example only, with reference to the attached figures.

FIG. 1 is an exploded, isometric view of an embodiment of a heat dissipating system.

FIG. 2 is a heat dissipating device of the heat dissipating system of FIG. 1.

FIG. 3 is an assembled view of the heat dissipating system of FIG. 1.

FIG. 4 is a side view of the heat dissipating device and a motherboard of the heat dissipating system of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is described in relation to a heat dissipating device. The heat dissipating device includes a storage tank for storing cooling liquid, a driving device located in the storage tank, a heat sink configured to be located above an electronic component, and a cooling tube circulating throughout the heat sink. The storage tank includes an outlet and an intake. A first end of the cooling tube is coupled to the outlet, and a second opposite end of the cooling tube is coupled to the intake. The driving device is used to move the cooling liquid out of the storage tank via the outlet to extend through the cooling pipe, and flow back to the storage tank via the intake for dissipating heat generated by the electronic component.

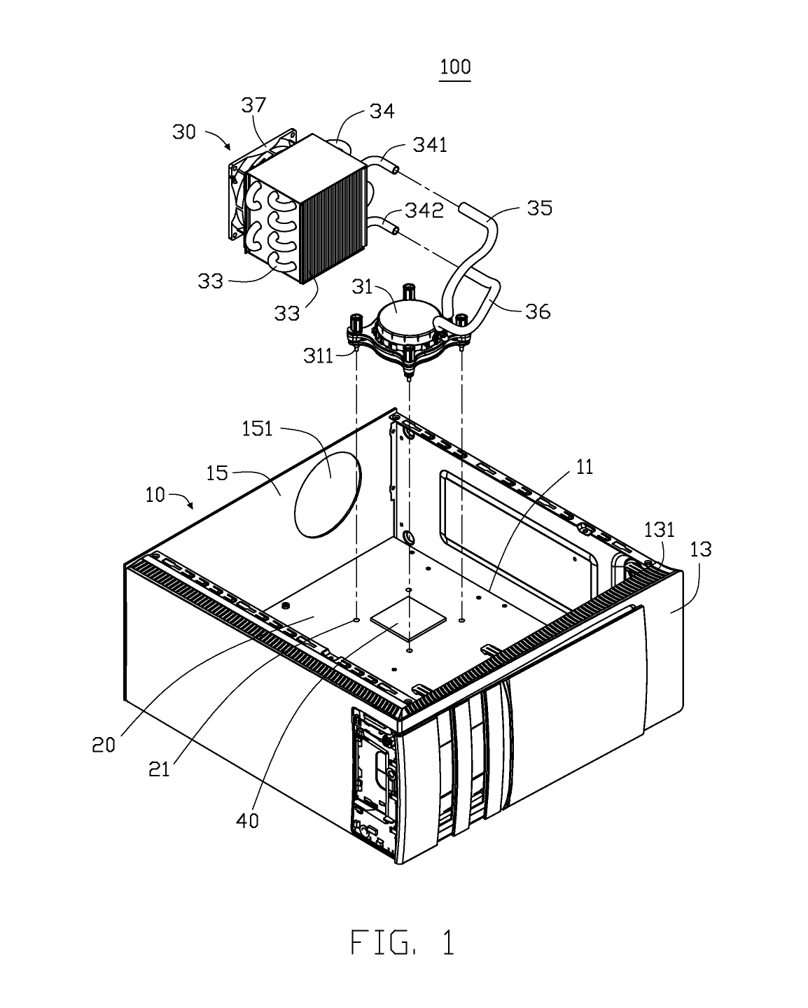

FIG. 1 illustrates an embodiment of a heat dissipating system 100. The heat dissipating system 100 includes an electronic device 10 and a heat dissipating device 30 received in the electronic device 10. In at least one embodiment, the electronic device 10 can be a computer, which comprises an enclosure and a plurality of electronic components.

The electronic device 10 includes a bottom plate 11, a front plate 13, and a rear plate 15 opposite to the bottom plate 11. In at least one embodiment, the front plate 13 is substantially parallel to the rear plate 15 and perpendicular to the bottom plate 11. A motherboard 20 comprising a plurality of electronic components is attached to the bottom plate 11. The plurality of electronic components can include a Central Processing Unit (CPU) 40. Four mounting holes 21 are defined in the motherboard 20 and are arranged at four corners of the CPU 40. A plurality of first ventilation holes 131 is defined in the front plate 13, and a second ventilation hole 151 is defined in the rear plate 15.

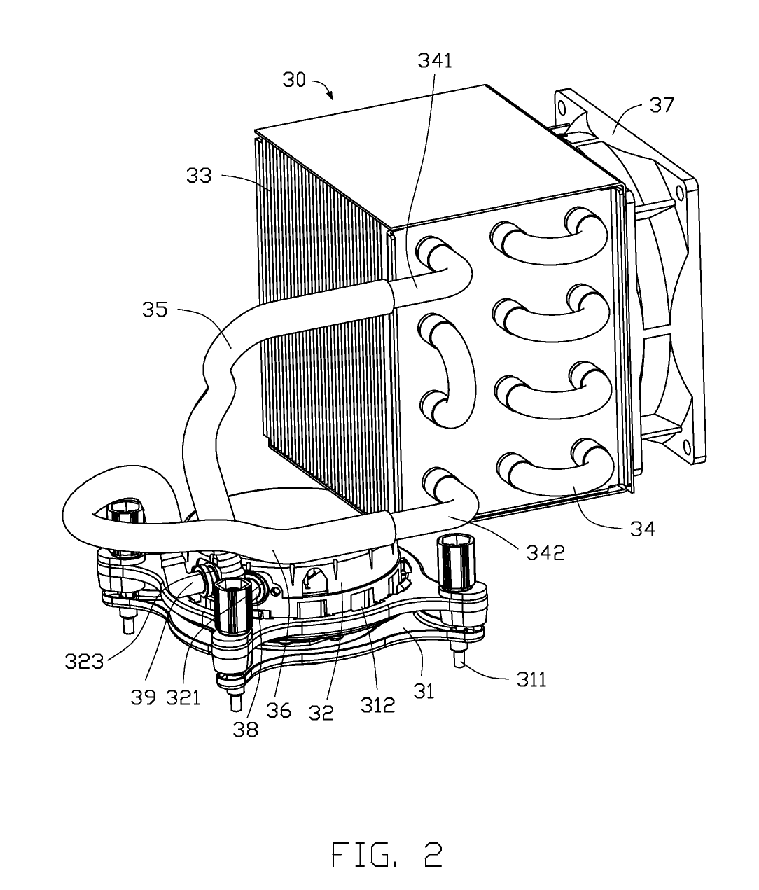

FIG. 2 illustrates an embodiment of the heat dissipating device 30 of the heat dissipating system 100. The heat dissipating device 30 includes a securing member 31, a storage tank 32, a heat sink 33, a cooling tube 34 circulating throughout the heat sink 33, a first flex pipe 35, a second flex pipe 36, and a fan 37 attached to a side of the heat sink 33. The first flex pipe 35 can be coupled to a first end 341 of the cooling tube 34, and the second flex pipe 36 can be coupled to a second opposite end 342 of the cooling tube 34.

The securing member 31 can be configured to secure the CPU 40 to the motherboard 20 and includes four securing posts 311. The four securing posts 311 can be engaged in the four mounting holes 21 to secure the securing member 21 to the motherboard 20. A receiving hole 312 is defined in the securing member 21 for receiving a storage tank 32.

The storage tank 32 is secured to the securing member 32 and is received in the receiving hole 312. The storage tank 32 can store cooling liquid, such as water. The storage tank 32 can include an outlet 321 and an intake 323. A first end of the first flex pipe 35 is secured to the outlet 321 by a first mounting member 38, and a second end of the first flex pipe 35 is coupled to the first end 341 of the cooling pipe 34. A first end of the second flex pipe 36 is secured to the intake 323 by a second mounting member 39, and a second end of the second flex pipe 36 is coupled to the second end 342 of the cooling tube 34.

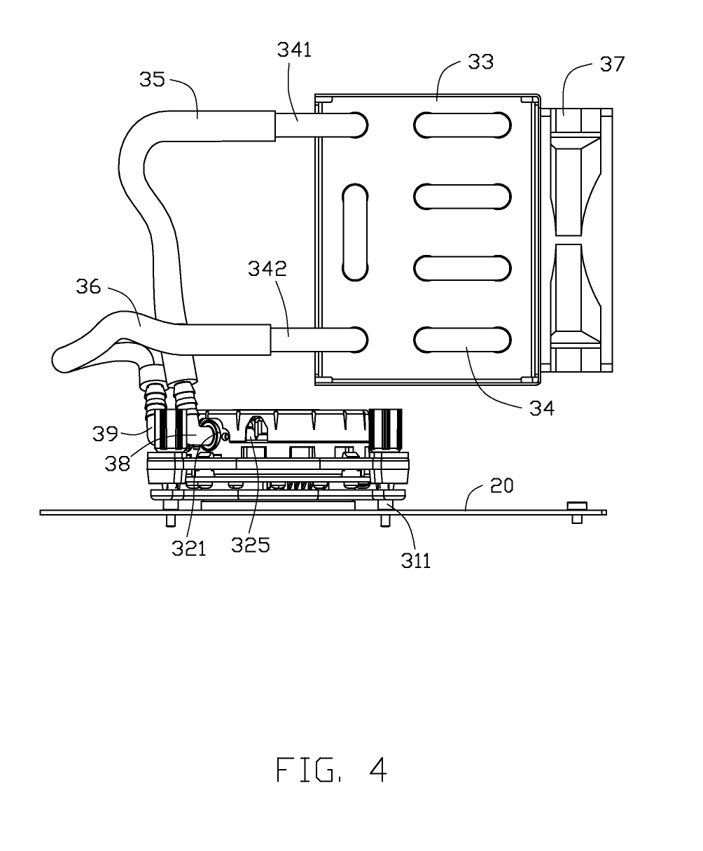

A driving device 325 (see FIG. 4) is located in the storage tank 32. The driving device 325 is configured to move the cooling liquid out of the storage tank 32 via the outlet 321 to flow through the first flex pipe 35, the cooling pipe 341 and the second flex pipe 36 in turn, and flow back to the storage tank 32 via the intake 323. Therefore, heat in the heat sink 33 can be taken away by the cooling tube 34 with the cooling liquid.

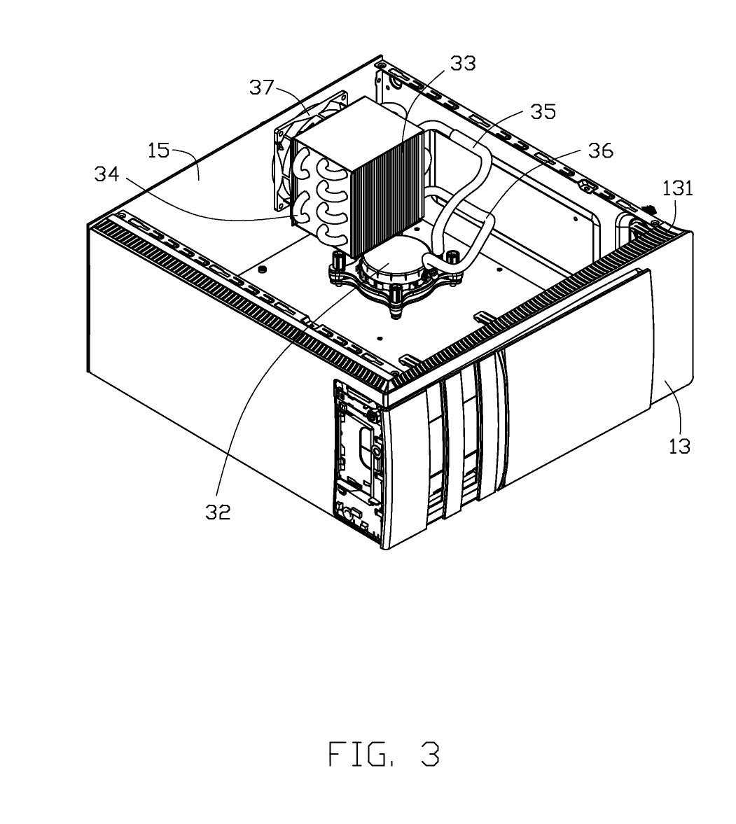

FIG. 3 illustrates an assembled view of the heat dissipating system 100. The first end of the first flex pipe 35 is secured to the outlet 321 by the first mounting member 38, and the second end of the first flex pipe 35 is coupled to the first end 341 of the cooling pipe 34. The first end of the second flex pipe 36 is secured to the intake 323 by the second mounting member 39, and the second end of the second flex pipe 36 is coupled to the second end 342 of the cooling tube 34. The securing member 31 is located above the CPU 40, and the securing posts 311 are engaged in the mounting holes 21 to secure the securing member 31 to the motherboard 40. The fan 37 is aligned with the second ventilation hole 151 and is secured to the rear plate 15 by means, such as screws or clips.

FIG. 4 illustrates a side view of the heat dissipating device 30 and the motherboard 20. In use, the CPU 40 works to generate heat. Air flows into the electronic device 30 via the first ventilation holes 131, then flows through the heat sink 33 via the fan 37, and is forced out of the electronic device 10 by the second ventilation hole 151. In addition, the driving device 325 moves the cooling liquid out of the storage tank 32 via the outlet 321 to flow through the first flex pipe 35, the cooling pipe 341 and the second flex pipe 36 in turn, and flow back to the storage tank 32 via the intake 323. Therefore, heat in the heat sink 33 can be taken away by the cooling tube 34 with the cooling liquid, and the heat generated by the CPU can be effectively dissipated by the heat dissipating device 30.

The embodiments shown and described above are only examples. Many details are often found in the art such as the other features of a heat dissipating device. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A heat dissipating device comprising:
a storage tank configured to store cooling liquid, the storage tank comprising an outlet and an intake;
a heat sink located above an electronic component;
a driving device located in the storage tank; and
a cooling tube circulating within the heat sink, a first end of the cooling tube configured to couple with the outlet, and a second opposite end of the cooling tube configured to couple with the intake,
wherein the driving device is configured to move, via the cooling tube, the cooling liquid out of the storage tank via the outlet in order to dissipate heat generated by the electronic component.

2. The heat dissipating device of claim 1, wherein the heat dissipating device further comprises a first flex pipe and a second flex pipe, the first end of the cooling tube is coupled to the outlet by the first flex pipe, and the second end of the cooling tube is coupled to the intake by the second flex pipe.

3. The heat dissipating device of claim 2, wherein the heat dissipating device further comprises a first mounting member and a second mounting member, the first mounting member is configured to secure the first flex pipe to the outlet, and the second mounting member is configured to secure the second flex pipe to the intake.

4. The heat dissipating device of claim 1, wherein the heat dissipating device further comprises a securing member configured to secure to a motherboard, and the storage tank is secured to the securing member.

5. The heat dissipating device of claim 4, wherein the securing member defines a receiving hole, and the storage tank is received in the receiving hole.

6. The heat dissipating device of claim 1, wherein the heat dissipating device further comprises a fan, and the fan is attached to the heat sink.

7. The heat dissipating device of claim 1, wherein the driving device is pump.

8. The heat dissipating device of claim 1, wherein the cooling liquid is water.

9. A heat dissipating system comprising:
an electronic device comprising a bottom plate, a front plate, and a rear plate; a motherboard, with an electronic component, located on the bottom plate, the front plate defining a first ventilation hole, and the rear plate defining a second ventilation hole; and
a heat dissipating device located on the comprising:
a storage tank configured to store cooling liquid; the storage tank comprising an outlet and an intake;
a heat sink located above the electronic component;
a driving device located in the storage tank; and
a cooling tube circulating within the heat sink; a first end of the cooling tube configured to couple with the outlet, and a second opposite end of the cooling tube configured to couple with the intake;
wherein the first ventilation hole, the heat sink and the second ventilation hole cooperatively defines a passage for air extending through; the driving device is configured to move the cooling liquid out of the storage tank via the outlet to extend through the cooling pipe, and flow back to the storage tank via the intake in order to dissipate heat generated by the electronic component.

10. The heat dissipating system of claim 9, wherein the heat dissipating device further comprises a first flex pipe and a second flex pipe, the first end of the cooling tube is coupled to the outlet by the first flex pipe, and the second end of the cooling tube is coupled to the intake by the second flex pipe.

11. The heat dissipating system of claim 10, wherein the heat dissipating device further comprises a first mounting member and a second mounting member, the first mounting member is configured to secure the first flex pipe to the outlet, and the second mounting member is configured to secure the second flex pipe to the intake.

12. The heat dissipating system of claim 9, wherein the heat dissipating device further comprises a securing member configured to secure to the motherboard, and the storage tank is secured to the securing member.

13. The heat dissipating system of claim 12, wherein the securing member defines a receiving hole, and the storage tank is received in the receiving hole.

14. The heat dissipating system of claim 9, wherein the heat dissipating device further comprises a fan attached to the heat sink, and the fan is aligned with the second ventilation hole and is secured to the rear plate.

15. The heat dissipating system of claim 9, wherein the driving device is pump.

16. The heat dissipating system of claim 9, wherein the cooling liquid is water.

17. The heat dissipating system of claim 9, wherein the front plate is substantially parallel to the rear plate and is perpendicular to the bottom plate.
